(19) United States
(12) Patent Application Publication
(10) Pub. No.: US 2026/0312491 A1
(43) Pub. Date: Oct. 8, 2026

(54) CHARGE PUMP CIRCUIT INCLUDING OUTPUT TERMINAL-CONNECTED PRE-CHARGE CIRCUIT

(71) Applicant: GlobalFoundries U.S. Inc., Malta, NY (US)

(72) Inventors: Siva Kumar Chinthu, Bangalore (IN); Suresh Pasupula, Andhra Pradesh (IN); Harsh Maurya, Bangalore (IN)

(21) Appl. No.: 19/098,028

(22) Filed: Apr. 2, 2025

(51) Int. Cl. H02M 3/07; G11C 5/14; H03K 19/0185

(52) U.S. Cl. CPC H02M 3/07; G11C 5/145; H03K 19/018521

(57) ABSTRACT

Disclosed is a charge pump circuit with an output terminal-connected pre-charge circuit for reducing the startup time required to achieve a stable output voltage (VOUT). The circuit structure includes an output terminal for outputting VOUT and, connected to the output terminal, both a charge pump (CP) and a pre-charge circuit. A first section of the pre-charge circuit includes a pull-up transistor connected to the output terminal for performing a first pre-charge operation to pull up VOUT from 0.0 volts to a first positive voltage level when CP is initially enabled. A second section of the pre-charge circuit includes a buffer circuit and a capacitor series-connected to the output terminal for performing a second pre-charge operation to further boost VOUT to a second positive voltage level. The pre-charge circuit is controlled, at least in part, by a charge pump enable signal and a delayed charge pump enable signal.

### BACKGROUND

The present disclosure relates to charge pump circuits and, more particularly, to embodiments of a charge pump circuit with an output terminal-connected pre-charge circuit for improved (i.e., faster) startup time and a method of operating the charge pump circuit.

Memory circuits (e.g., resistive random access memory (RRAM) circuits or other memory circuits) and other modern integrated circuits (ICs) may require the use of a higher positive voltage than the available positive supply voltage (VDD). Typically, such circuits include a charge pump with cross-coupled transistors and internal capacitors to generate a stable relatively high positive output voltage (VOUT) (e.g., VOUT~2*VDD). However, with a conventional charge pump, the startup time required to achieve a stable VOUT when transitioning from a power off state to a power on state can be relatively long (e.g., hundreds of nanoseconds (ns) and often over 400 ns). Depending upon the application, this long start-up time can negatively impact circuit performance (e.g., increase the write time in a RRAM and thereby negatively impact RRAM endurance cycles, power consumption, etc.).

### SUMMARY

Disclosed herein are embodiments of a charge pump circuit structure with an output terminal-connected pre-charge circuit for reducing the startup time required to achieve a stable output voltage (VOUT) when transitioning from a power off state to a power on state. Specifically, in the disclosed embodiments, the circuit structure can include an output terminal and a charge pump connected to the output terminal. The circuit structure can also include a pre-charge circuit. The pre-charge circuit can include two pre-charge sections (i.e., a first section and a second section). The first section can include a pull-up transistor connected to the output terminal. The second section can include a buffer circuit; and a capacitor connected between the buffer circuit and the output terminal.

In some embodiments, the circuit structure can include an output terminal and a charge pump connected to the output terminal. The circuit structure can further include a pre-charge circuit including a delay circuit, a first section, and a second section. The delay circuit can be connected to receive a charge pump enable signal (CP_EN). The delay circuit can further output a delayed charge pump enable signal (CP_ENd). The first section can include a pull-up transistor, a logic circuit, and a level shifter. The pull-up transistor can be connected to the output terminal. The logic circuit can be connected to receive CP_EN and CP_ENd. The logic circuit can further output a digital control signal (CS). The level shifter can be connected to receive CS from the logic circuit and an output voltage (VOUT) from the output terminal. The level shifter can further output a gate voltage (VG) to the gate of the pull-up transistor and this VG can be variable depending upon the voltage levels of CS and VOUT. During a first pre-charge operation, the VG can cause the pull-up transistor to turn on in order to pull VOUT up to a first positive voltage level. The second section can include a buffer circuit and a capacitor, which is connected between the buffer circuit and the output terminal. The buffer circuit can be connected to receive CP_ENd. During a second pre-charge operation, CP_ENd can go high and buffer circuit can output a buffer signal (Vbuff) to the capacitor to further boost VOUT to a second positive voltage level.

In some embodiments, the circuit structure can include an output terminal and a charge pump connected to the output terminal. The circuit structure can further include a pre-charge circuit including a programmable delay circuit, a first section, and a second section. The delay circuit can be connected to receive a charge pump enable signal (CP_EN) and trim bits. The delay circuit can further output a delayed charge pump enable signal (CP_ENd) based on the trim bits. The first section can include a pull-up transistor, a logic circuit, and a level shifter. The pull-up transistor can be connected to the output terminal. The logic circuit can be connected to receive CP_EN and CP_ENd. The logic circuit can further output a digital control signal (CS). The level shifter can be connected to receive CS from the logic circuit and an output voltage (VOUT) from the output terminal. The level shifter can further output a gate voltage (VG) to the gate of the pull-up transistor and this VG can be variable depending upon the voltage levels of CS and VOUT. During a first pre-charge operation, the VG can cause the pull-up transistor to turn on in order to pull VOUT up to a first positive voltage level. The second section can include a buffer circuit and a capacitor, which is connected between the buffer circuit and the output terminal. The buffer circuit can be connected to receive CP_ENd. During a second pre-charge operation, CP_ENd can go high and buffer circuit can output a buffer signal (Vbuff) to the capacitor to further boost VOUT to a second positive voltage level.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating disclosed embodiments of a charge pump circuit structure with an output terminal-connected pre-charge circuit;

FIG. 2 is a schematic diagram illustrating one example of a charge pump that can be incorporated into the circuit structure of FIG. 1;

FIG. 3 is a schematic diagram illustrating one example of a programmable delay circuit that can be incorporated into the pre-charge circuit of the circuit structure of FIG. 1;

FIG. 4 is a schematic diagram illustrating one example of a level shifter that can be incorporated into the pre-charge circuit of the circuit structure of FIG. 1; and

FIG. 5 is a timing diagram illustrating various signals exhibited during operation of the circuit structure of FIG. 1.

### DETAILED DESCRIPTION

As mentioned above, memory circuits (e.g., resistive random access memory (RRAM) circuits or other memory circuits) and other modern integrated circuits (ICs) may require the use of a higher positive voltage than the available positive supply voltage (VDD). Typically, such circuits include a charge pump with cross-coupled transistors and internal capacitors to generate a stable relatively high positive output voltage (VOUT) (e.g., a VOUT~2*VDD). However, with a conventional charge pump, the startup time required to achieve a stable VOUT when transitioning from a power off state to a power on state can be relatively long (e.g., hundreds of nanoseconds (ns) and often over 400 ns). Depending upon the application, this long start-up time can negatively impact circuit performance (e.g., increase the write time in a RRAM and thereby negatively impact RRAM endurance cycles, power consumption, etc.). One conventional technique used to pre-charge VOUT is connection of stacked metal oxide semiconductor capacitors (MOSCAPs) to the output of the charge pump to provide a sufficient amount of load capacitance. However, the stacked MOSCAPS consume a significant amount of chip area.

In view of the foregoing disclosed herein are embodiments of a charge pump circuit with an output terminal-connected pre-charge circuit for reducing the startup time required to achieve a stable output voltage (VOUT) when transitioning from a power off state to a power on state. Specifically, the disclosed embodiments include a circuit structure with an output terminal for outputting an output voltage (VOUT) and, connected to the output terminal, both a charge pump (CP) and a pre-charge circuit. The pre-charge circuit includes two pre-charge sections (i.e., a first section and a second section). The first section can include a pull-up transistor connected to the output terminal and can be configured to perform a first pre-charge operation to pull up VOUT from 0.0 volts (V) to a first positive voltage level when CP is initially enabled (i.e., when the supply voltage provided by a supply voltage node to CP switches from 0.0V to the first positive voltage level). The second section can include a buffer circuit and a capacitor series-connected to the output terminal and can be configured to perform a second pre-charge operation to further boost VOUT from the first positive voltage level to a second positive voltage level (which is approximately twice the first positive voltage level). Operation of the pre-charge circuit can be controlled, at least in part, by a charge pump enable signal (CP_EN) and a delayed charge pump enable signal (CP_ENd) (from a delay circuit). Optionally, the delay circuit can be a programmable delay circuit to fine tune control of the first and second pre-charge operations.

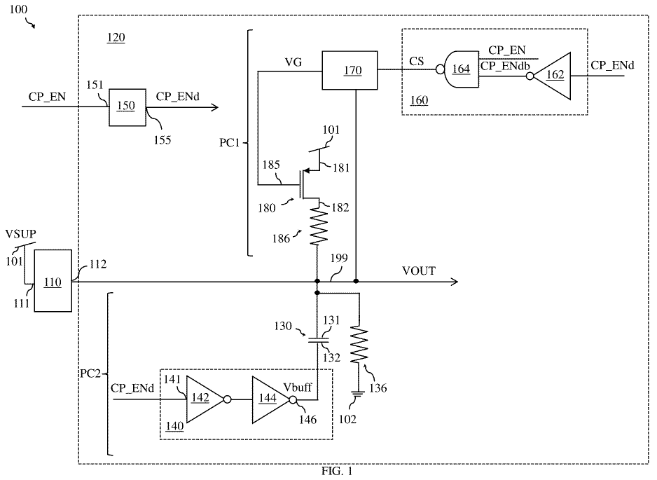

More particularly, FIG. 1 is a schematic diagram illustrating embodiments of a charge pump circuit structure 100 (referred to herein after as circuit structure 100) with an output terminal-connected pre-charge circuit 120 for reducing the startup time required to achieve a stable output voltage (VOUT) when transitioning from a power off state to a power on state. Specifically, circuit structure 100 can include: an output terminal 199 for outputting VOUT; and, connected to output terminal 199, both a charge pump (CP) 110 and a pre-charge circuit 120.

CP 110 can include a CP input node 111 and a CP output node 112. CP input node 111 can be electrically connected to a supply voltage node 101. Supply voltage node 101 (and, thereby CP input node 111) can be connected to receive a supply voltage (VSUP). VSUP can switch between 0.0 volts (V) when circuit structure 100 is powered off (i.e., when CP 110 is disabled) and a first positive voltage level (VDD) (e.g., of 1.8V) when circuit structure 100 is powered on (i.e., when CP 110 is enabled). CP 110 can further be configured to generate a VOUT on CP output node 112, when enabled, such that VOUT is at a second positive voltage level greater than the first positive voltage level. In some embodiments, this second positive voltage level can be approximately equal to twice the first positive voltage level (2*VDD) (e.g., at ~3.6V). Those skilled in the art will recognize that the actual VOUT may be slightly less than 2*VDD due to some inherent voltage drop between the CP input and output nodes 111-112. For example, if VDD is 1.8V, the actual VOUT of CP 110 when enabled may be less than 3.6V by approximately 0.2V (e.g., VOUT may be 3.4V)

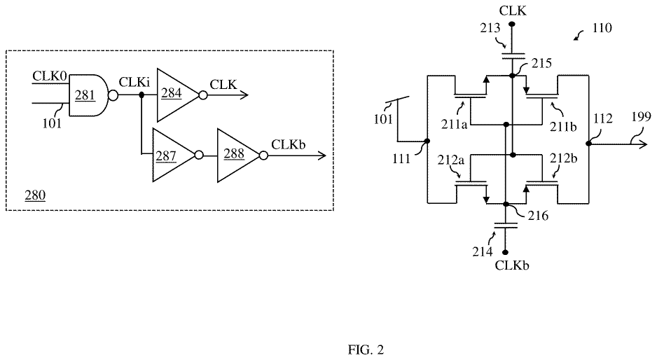

In some embodiments, as illustrated in FIG. 2, CP 110 can include cross-coupled transistors and internal capacitors to generate a high positive VOUT (e.g., VOUT~2*VDD). Specifically, CP 110 can include a first pair of transistors including: a first N-type field effect transistor (NFET) 211a and a first P-type field effect transistor (PFET) 211b connected in series between CP input node 111 and CP output node 112. CP 110 can further include a second pair of transistors including: a second NFET 212a and second PFET 212b connected in series between CP input node 111 and CP output node 112. These transistors can be cross-coupled. That is, a first junction 215 (i.e., an electric connection or other interconnect) between first NFET 211a and first PFET 211b can be electrically connected to the gates of second NFET 212a and second PFET 212b and a second junction 216 (i.e., an electric connection or other interconnect) between second NFET 212a and second PFET 212b can be electrically connected to the gates of first NFET 211a and first PFET 211b. CP 110 can further include a first capacitor 213 with first capacitor plates separated by a first capacitor dielectric. One first capacitor plate can be electrically connected to the first junction 215 and another first capacitor plate can be electrically connected to receive a clock signal (CLK). CP 110 can further include a second capacitor 214 with second capacitor plates separated by a second capacitor dielectric. One second capacitor plate can be electrically connected to the second junction 216 and another second capacitor plate can be electrically connected to receive an inverted clock signal (CLKb).

As illustrated in FIG. 2, CLK and CLKb can be generated by a clock signal generator 280. In some embodiments, clock signal generator 280 can include a NAND gate 281 with one input connected to receive a system clock signal (CLK0) and another input connected to supply voltage node 101. NAND gate 281 can be configured to output an intermediate clock signal (CLKi) according to a conventional NAND gate truth table. That is, CLKi will only be low (i.e., at 0.0V) when CLK0 and the voltage level at supply voltage node 101 are both at the first positive voltage level (VDD). Clock signal generator 280 can further include an inverter 284 electrically connected to receive CLKi and a pair of series-connected inverters 287-288 also connected to receive CLKi. Inverter 284 can output CLK and Inverter 288 can output CLKb. Therefore, within clock signal generator 280, when VSUP at supply voltage node 101 is at VDD, CLKi will swing between 0.0V and VDD as CLK0 swings between VDD and 0.0V, thereby causing CLK to swing between VDD and 0.0V and CLKb to swing between 0.0V and VDD.

Within CP 110, when VSUP at supply voltage node 101 is steady at VDD, CLK switches to 0.0V, and CLKb switches to VDD, the voltage signal at first junction 215 drops turning off the second NFET 212a and turning on second PFET 212b and the voltage signal at second junction 216 rises turning on first NFET 211a and turning off first PFET 211b. When CLK switches to VDD and CLKB switches to 0.0V, the voltage signal at first junction 215 rises to VDD turning on second NFET 212a and turning off second PFET 212b and the voltage signal at second junction 216 drops to 0.0V turning off first NFET 211 a and turning on first PFET 211b. As a result, VOUT at CP output node 112 is continuously pulled up to the second positive voltage level (approximately 2*VDD), regardless whether CLK is at 0.0V or at VDD. In other words, VOUT at CP output node 112 and, thereby at output terminal 199 will be steady at approximately 2*VDD.

However, as discussed above, the startup time required to achieve a stable VOUT at CP output node 112 when transitioning from a power off state to a power on state can be relatively long (e.g., hundreds of nanoseconds (ns) and often over 400 ns). Therefore, referring again to FIG. 1, in order to boost VOUT on output terminal 199 when CP 110 is initially enabled and until such time as CP 110 can independently achieve a stable VOUT at the second positive voltage level (approximately 2*VDD), circuit structure 100 further includes pre-charge circuit 120.

Pre-charge circuit 120 can include a delay circuit 150 and two pre-charge sections (i.e., a first section (PC1) and a second section (PC2)).

Delay circuit 150 can include a delay circuit input node 151 and a delay circuit output node 155. Delay circuit input node 151 can be connected to receive a charge pump enable signal (CP_EN). CP_EN can, for example, be received from a system controller (not shown) and switch between 0.0V and the first positive voltage level (VDD) when CP 110 is disabled (i.e., powered off) and enabled (i.e., powered on), respectively. Delay circuit 150 can further be configured to output a delayed charge pump enable signal (CP_ENd) at delay circuit output node 155. Delay circuit 150 can be a fixed delay circuit, which outputs CP_ENd with a fixed amount of delay relative to CP_EN. That is, the time period between the rising edge of CP_EN and the rising edge of CP_ENd will be a fixed time period. Various different configurations for fixed delay circuits are known in the art and, thus, the details thereof have been omitted from this specification in order to allow the reader to focus on the salient aspects of the disclosed embodiments (e.g., related to the configurations of the first and second sections of pre-charge circuit 120).

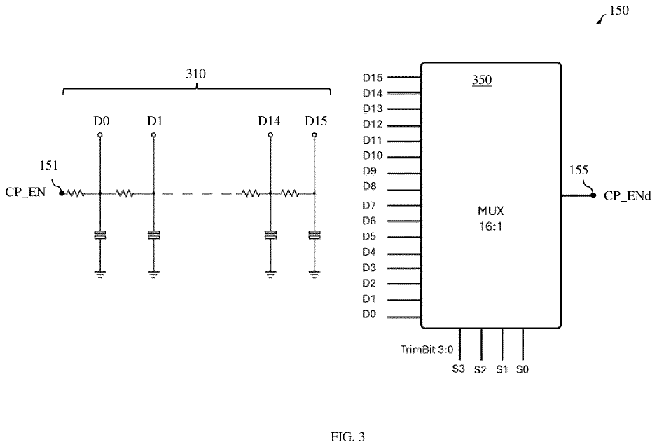

Alternatively, delay circuit 150 could be a programmable delay circuit, which outputs CP_ENd with some pre-selected (i.e., programmed) amount of delay relative to CP_ENd. That is, the time period between the rising edge of CP_EN and the rising edge of CP_ENd can be a selectively variable time period in order to fine to the pre-charge operations (as discussed in greater detail below). FIG. 3 is a schematic diagram illustrating one example of a programmable delay circuit that can be incorporated into pre-charge circuit 120 of FIG. 1 as delay circuit 150. As illustrated, this programmable delay circuit can include a delay stage 310. Delay stage 310 can include: the delay circuit input node 151 connected to receive CP_EN; a chain of resistors connected at one end to the delay circuit input node 151; taps between adjacent resistors in the chain; and capacitors connected between the taps and ground. With this configuration, the taps can output delayed versions of CP_EN with progressively increasing delays. This programmable delay circuit can also include a multiplexer (MUX) 350. MUX 350 can be connected to receive each of the delayed versions of CP_EN and can further be connected to receive a set of trim bits that control which one of the delayed versions of CP_EN will be output at delayed circuit output node 155. For purposes of illustration, delay stage 310 is shown as including sixteen taps outputting sixteen delayed versions (D0-D15) of CP_EN to MUX 350. In this case, MUX 350 receives D0-D15 and further receives four trim bits (i.e., trim bits <3:0>) that control which of one of D0-D15 is output at delayed circuit output node 155.

Referring again to FIG. 1, PC1 can be connected to output terminal 199 and can be configured to perform a first pre-charge operation during which VOUT at output terminal 199 is boosted from 0.0V to the first positive voltage level (VDD) when CP 110 is initially enabled (i.e., when VSUP on supply voltage node 101 switches from 0.0V to VDD).

PC1 can include a pull-up transistor 180. Pull-up transistor 180 can be a P-type field effect transistor (PFET) including: a source region 181, which is electrically connected to supply voltage node 101; a drain region 182, which is electrically connected to output terminal 199 (optionally, via a resistor 186); a channel region positioned laterally between source region 181 and drain region 182; and a gate adjacent to the channel region.

PC1 can further include a logic circuit 160 and a voltage level shifter 170 (also referred to herein as level shifter 170) for controlling the on/off state of pull-up transistor 180. Specifically, logic circuit 160 can be electrically connected to receive CP_EN and CP_ENd. Logic circuit 160 can further be configured to output a digital control signal (CS). CS can switch between 0.0V and the first positive voltage level (VDD) depending upon the voltage levels of CP_EN and CP_ENd. For example, logic circuit 160 can include an inverter 162, which is electrically connected to receive CP_ENd and which is configured to output an inverted delayed charge pump enable signal (CP_ENdb). Logic circuit 160 can further include a NAND gate 164, which is electrically connected to receive CP_EN and CP_ENdb, as inputs. NAND gate 164 can be configured to output CS according to a conventional NAND gate truth table. That is, CS will only go low (i.e., to 0.0V) when CP_EN and CP_ENdb are both at the first positive voltage level (VDD). Otherwise, CS will be at the first positive voltage level (VDD).

Level shifter 170 can be electrically connected to receive, as inputs, VOUT from output terminal 199 and CS from NAND gate 164. Level shifter 170 can further be configured to output a gate voltage (VG) to gate 185 of pull-up transistor 180. VG from level shifter 170 controls the on/off state of pull-up transistor 180 and is variable depending upon the voltage levels of both CS and VOUT. For example, level shifter 170 can be configured to switch VG to 0.0V when CS is 0.0 volts (V) and VOUT is at 0.0V when CP 110 is initially enabled (i.e., powered on) in order to initiate the first pre-charge operation during which pull-up transistor 180 turns and, thus, VOUT is pulled up to the first positive voltage level (VDD).

PC2 can also be connected to output terminal 199 and can be configured to perform a second pre-charge operation. During the second pre-charge operation, VOUT on output terminal 199 is further boosted from the first positive voltage level (VDD) to the second positive voltage level (approximately 2*VDD) faster than would be achieved without pre-charge circuit 120. Specifically, PC2 can include a buffer circuit 140 and a capacitor 130. Buffer circuit 140 can include: a buffer input node 141, which is electrically connected to receive CP_ENd; and a buffer output node 146, which outputs a buffer signal (Vbuff). In some embodiments, buffer circuit 140 can include a pair of series-connected inverters 142 and 144, as illustrated. Capacitor 130 can include, for example, a single metal oxide semiconductor capacitor (MOSCAP) (e.g., a 1.8V rated MOSCAP when VDD is 1.8V) or any other suitable capacitor. In any case, capacitor 130 can include capacitor plates 131-132 separated by a capacitor dielectric. Capacitor plates 131-132 can be electrically connected to output terminal 199 and to buffer output node 146, respectively. Optionally, PC2 can also include a resistor 136 with end terminals connected to the output terminal 199 and ground 102. With this configuration, after CP_ENd switches to the first positive voltage level (VDD), Vbuff will switch to the first positive voltage level (VDD), thereby initiating a second pre-charge operation during which capacitor 130 boosts VOUT by the first positive voltage level (VDD) so that, in combination, the two pre-charge operations ultimately raise VOUT to the second positive voltage level (approximately 2*VDD).

When CP_ENd switches to the first positive voltage level (VDD) after the delay (fixed or programmed) relative to CP_EN, CP_ENdb will drop back to 0.0V and CS from NAND gate 164 will switch from 0.0V back to the first positive voltage level (VDD). In response, the level shifter 170 can switch VG from 0.0V to VOUT to turn off pull-up transistor 180. It should be noted that the amount of delay between CP_EN and CP_ENd can be predetermined and either fixed or selected (depending upon the type of delay circuit used) to ensure that pull-up transistor 180 remains on until VOUT reaches the first positive voltage level (VDD) and then switches off.

As noted above, due to the second pre-charge operation VOUT continues to rise until it reaches the second positive voltage level (approximately 2*VDD). Level shifter 170 can further be configured so that VG tracks VOUT when CS is at the first positive voltage level (VDD) so that VG will also continue to rise until it reaches the second positive voltage level (approximately 2*VDD), thereby ensuring that pull-up transistor 180 remains off when VOUT is above the first positive voltage level (VDD).

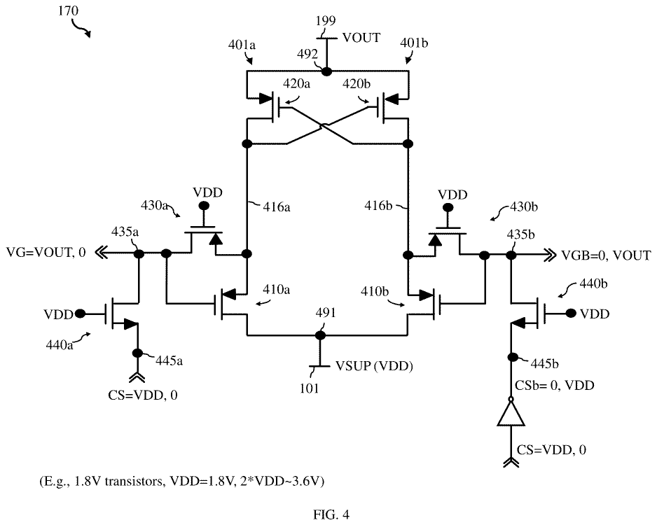

FIG. 4 is a schematic diagram illustrating one example of a level shifter 170 that can be incorporated into the circuit structure 100 of FIG. 1 and operate as described above. Referring to FIG. 4 in combination with FIG. 1, in this example, level shifter 170 can include symmetric branches 401a-401b connected in parallel between first and second voltage nodes 491 and 492, respectively. First voltage node 491 can be electrically connected to supply voltage node 101 to receive VSUP (which switches to the first positive voltage level (VDD) when CP 110 is powered on). Second voltage node 492 can be electrically connected to output terminal 199 to receive VOUT.

Each branch 401a, 401b can include a first PFET 410a, 410b and a second PFET 420a, 420b electrically connected in series between voltage nodes 491 and 492. Each branch 401a, 401b can further include a third PFET 430a, 430b electrically connected to a junction 416a, 416b between first PFET 410a, 410b and second PFET 420a, 420b. Third PFET 430a, 430b can specifically include: a source region, which is electrically connected to junction 416a, 416b; a drain region, which is electrically connected to a level shifter output node 435a, 435b and to the gate of first PFET 410a, 410b; and a gate 432a, 432b, which is electrically connected to voltage node 491. Additionally, second PFET 420a of branch 401a and second PFET 420b of branch 401b can be cross coupled. That is, the gate of second PFET 420a in branch 401a can be electrically connected to junction 416b between first PFET 410b and second PFET 420b in branch 401b, while the gate of second PFET 420b in branch 401b can be electrically connected to junction 416a between first PFET 410a and second PFET 420a in branch 401a.

Each branch 401a, 401b can further include an NFET 440a, 440b (also referred to herein as a pass-gate NFET). NFET 440a, 440b can include: a source region, which is electrically connected to a level shifter input node 445a, 445b; a drain region, which is electrically connected to a level shifter output node 435a, 435b; and a gate, which is electrically connected to first voltage node 491.

As illustrated, level shifter input node 445a can be connected to receive CS (from the NAND gate 164 of FIG. 1), level shifter input node 445b can be connected to receive an inverted version of CS (CSb) (e.g., from an inverter 470), and level shifter output node 435a can output VG (e.g., to the gate 185 of pull-up transistor 180 in FIG. 1 to control the on/off state of pull-up transistor 180).

With a level shifter 170, as described above, when CS applied to level shifter input node 445 a is low (i.e., at 0.0V), VG at level shifter output node 435 a will be at 0.0V. Furthermore, when CS applied to level shifter input node 445a goes high (i.e., to the first positive voltage level (VDD)), VG at level shifter output node 435a will switch to VOUT. Additionally, since VOUT is supplied to second voltage node 492, VG at level shifter output node 435a tracks VOUT. That is, when CS is at VDD and as VOUT rises from the first positive voltage level (VDD) to the second positive voltage level (approximately 2*VDD) due to boosting by PC2, VG also continues to rise to the second positive voltage level (approximately 2*VDD), thereby ensuring that pull-up transistor 180 remains off when VOUT is above the first positive voltage level (VDD).

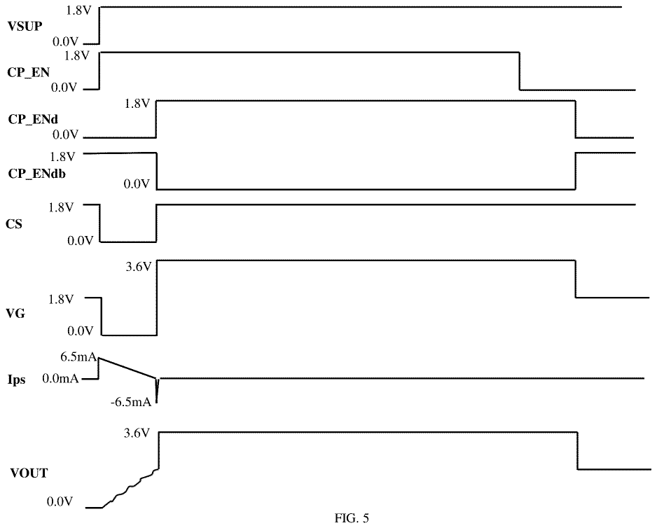

FIG. 5 is a timing diagram illustrating various signals exhibited within circuit structure 100 during power on. As illustrated, VSUP at supply voltage node 101 and CP_EN concurrently switch to the first positive voltage level (VDD) (e.g., 1.8V). CP_ENd switches to the first positive voltage level (VDD) after some predetermined delay and CP_ENdb switches to 0.0V. CS switches to 0.0V and stays at 0.0V only between the rising edges of CP_EN and CP_ENd, otherwise it stays at the first positive voltage level (VDD). VG drops from 1.8V to 0.0V when CS switches to 0.0V and rises to the second positive voltage level (approximately 2*VDD) (e.g., approximately 3.6V) when CS switches back to the first positive voltage level (VDD). When VG is at 0.0V, pull-up transistor 180 will be turned on. When VG switches to 3.6V, pull-up transistor 180 will turn off. Thus, current (Ips) through pull-up transistor will peak when VG switches to 0.0V and slowly decrease until pull-up transistor 180 is turned off. Additionally, VOUT at output terminal 199 will steadily increase to the first positive voltage level (VDD) when pull-up transistor 180 is turned on and will increase sharply to the second positive voltage level (approximately 2*VDD) when Vbuff rises to the first positive voltage level (VDD) (due to CP_ENd switching to the first positive voltage level (VDD)) and further boosts VOUT.

A circuit structure 100 configured with a pre-charge circuit 120, as described above, can effectively achieve a stable VOUT at output terminal 199 at a rate up to ten times faster than a charge pump alone. Additionally, it can do so using a single MOSCAP as capacitor 130 to limit any significant increase in chip area consumed by the pre-charge circuit 120. Furthermore, the single MOSCAP can be employed without violating any safe operating area (SOA) specifications. For example, if VDD is 1.8V, capacitor 130 can be a 1.8V MOSCAP. Given the pre-charge operations described above, the maximum voltage differential across the MOSCAP will not be more than 1.8V.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
an output terminal;
a charge pump connected to the output terminal; and
a pre-charge circuit including:
a first section including a pull-up transistor connected to the output terminal; and
a second section including: a buffer circuit; and a capacitor connected between the buffer circuit and the output terminal.

2. The structure of claim 1,
wherein the pre-charge circuit further includes: a delay circuit connected to receive a charge pump enable signal, and
wherein the delay circuit outputs a delayed charge pump enable signal to the first section and the second section.

3. The structure of claim 2, wherein the first section includes:
a logic circuit connected to receive the charge pump enable signal and the delayed charge pump enable signal, wherein the logic circuit outputs a digital control signal; and
a level shifter connected to receive the digital control signal and an output voltage from the output terminal, wherein the level shifter outputs a gate voltage to a gate of the pull-up transistor and wherein the gate voltage is variable depending upon the digital control signal and the output voltage.

4. The structure of claim 3, wherein the logic circuit includes:
an inverter connected to receive the delayed charge pump enable signal, wherein the inverter outputs an inverted delayed charge pump enable signal; and
a NAND gate connected to receive the charge pump enable signal and the inverted delayed charge pump enable signal, wherein the NAND gate outputs the digital control signal.

5. The structure of claim 4,
wherein, when the charge pump enable signal and the inverted delayed charge pump enable signal are at a first positive voltage level, the NAND gate switches the digital control signal to 0.0 volts (V) to initiate a first pre-charge operation in which the level shifter switches the gate voltage to 0.0V, the pull-up transistor turns on and the output voltage is pulled up to the first positive voltage level, and
wherein, when the inverted delayed charge pump enable signal switches to 0.0V, the NAND gate switches the digital control signal to the first positive voltage level.

6. The structure of claim 5,
wherein the capacitor includes capacitor plates connected to the buffer circuit and to the output terminal, respectively
wherein the buffer circuit is connected to receive the delayed charge pump enable signal,
wherein, when the delayed charge pump enable signal switches to the first positive voltage level, the buffer circuit outputs a buffer signal at the first positive voltage level to the capacitor to initiate a second pre-charge operation in which the output voltage is boosted to a second positive voltage level approximately equal to two times the first positive voltage level, and
wherein, when the output voltage switches to the second positive voltage level and the digital control signal is at the first positive voltage level, the level shifter switches the gate voltage to the second positive voltage level ensuring that the pull-up transistor turns off.

7. The structure of claim 1, wherein the buffer circuit includes a pair of series-connected inverters.

8. The structure of claim 1, wherein the second section further includes a resistor connected between the output terminal and a ground rail.

9. The structure of claim 1, wherein the pull-up transistor includes a p-type field effect transistor.

10. The structure of claim 1, wherein the first section further includes a resistor connected between the pull-up transistor and the output terminal.

11. The structure of claim 1, wherein the charge pump includes:
an output node connected to the output terminal;
an input node connected to a supply voltage node;
a first pair of transistors;
a second pair of transistors, wherein the first pair and the second pair each include an N-type field effect transistor and a P-type field effect transistor connected in series between the input node and the output node;
a first capacitor including first capacitor plates connected to a clock signal node and to a first junction between the transistors of first pair; and
a second capacitor including second capacitor plates connected to an inverted clock signal node and to a second junction between the transistors of second pair,
wherein first gates of the first pair are connected to the second junction and second gates of the second pair are connected to the first junction.

12. A structure comprising:
an output terminal;
a charge pump connected to the output terminal; and
a pre-charge circuit including:
a delay circuit connected to receive a charge pump enable signal, wherein the delay circuit outputs a delayed charge pump enable signal;
a first section including:
a pull-up transistor connected to the output terminal;
a logic circuit connected to receive the charge pump enable signal and the delayed charge pump enable signal, wherein the logic circuit outputs a digital control signal; and
a level shifter connected to receive the digital control signal and an output voltage from the output terminal, wherein the level shifter outputs a gate voltage to a gate of the pull-up transistor, and wherein the gate voltage is variable depending upon the digital control signal and the output voltage; and
a second section including:
a buffer circuit connected to receive the delayed charge pump enable signal; and
a capacitor connected between the buffer circuit and the output terminal.

13. The structure of claim 3, wherein the logic circuit includes:
an inverter connected to receive the delayed charge pump enable signal, wherein the inverter outputs an inverted delayed charge pump enable signal; and
a NAND gate connected to receive the charge pump enable signal and the inverted delayed charge pump enable signal, wherein the NAND gate outputs the digital control signal.

14. The structure of claim 13,
wherein, when the charge pump enable signal and the inverted delayed charge pump enable signal are at a first positive voltage level, the NAND gate switches the digital control signal to 0.0 volts (V) to initiate a first pre-charge operation in which the level shifter switches the gate voltage to 0.0V, the pull-up transistor turns on and the output voltage is pulled up to the first positive voltage level and
wherein, when the inverted delayed charge pump enable signal switches to 0.0V, the NAND gate switches the digital control signal to the first positive voltage level.

15. The structure of claim 14,
wherein the capacitor includes capacitor plates connected to the buffer circuit and to the output terminal, respectively,
wherein the buffer circuit is connected to receive the delayed charge pump enable signal,
wherein, when the delayed charge pump enable signal switches to the first positive voltage level, the buffer circuit outputs a buffer signal at the first positive voltage level to the capacitor to initiate a second pre-charge operation in which the output voltage is boosted to a second positive voltage level approximately equal to two times the first positive voltage level, and
wherein, when the output voltage switches to the second positive voltage level and the digital control signal is at the first positive voltage level, the level shifter switches the gate voltage to the second positive voltage level ensuring that the pull-up transistor turns off.

16. The structure of claim 12, wherein the buffer circuit includes a pair of series-connected inverters.

17. The structure of claim 12, wherein the second section further includes a resistor connected between the output terminal and a ground rail.

18. The structure of claim 12, wherein the first section further includes a resistor connected between the pull-up transistor and the output terminal.

19. The structure of claim 12, wherein the charge pump includes:
an output node connected to the output terminal;
an input node connected to a supply voltage node;
a first pair of transistors;
a second pair of transistors, wherein the first pair and the second pair each include an N-type field effect transistor and a P-type field effect transistor connected in series between the input node and the output node;
a first capacitor including first capacitor plates connected to a clock signal node and to a first junction between the transistors of first pair; and
a second capacitor including second capacitor plates connected to an inverted clock signal node and to a second junction between the transistors of second pair,
wherein first gates of the first pair are connected to the second junction and second gates of the second pair are connected to the first junction.

20. A structure comprising:
an output terminal;
a charge pump connected to the output terminal;
a programmable delay circuit connected to receive a charge pump enable signal and trim bits, wherein the programmable delay circuit outputs a delayed charge pump enable signal based on the trim bits; and
a pre-charge circuit including:
a first section including:
a pull-up transistor connected to the output terminal;
a logic circuit connected to receive the charge pump enable signal and the delayed charge pump enable signal, wherein the logic circuit outputs a digital control signal; and
a level shifter connected to receive the digital control signal and an output voltage from the output terminal, wherein the level shifter outputs a gate voltage to a gate of the pull-up transistor, and wherein the gate voltage is variable depending upon the digital control signal and the output voltage; and
a second section including:
a buffer circuit connected to receive the delayed charge pump enable signal; and
a capacitor connected between the buffer circuit and the output terminal.
